(19) United States
(12) Patent Application Publication
(10) Pub. No.: US 2014/0199833 A1
(43) Pub. Date: Jul. 17, 2014

(54) METHODS FOR PERFORMING A VIA REVEAL ETCHING PROCESS FOR FORMING THROUGH-SILICON VIAS IN A SUBSTRATE

(71) Applicant: Applied Materials, Inc., Santa Clara, CA (US)

(72) Inventors: Rohit MISHRA, Santa Clara, CA (US); Khalid Mohiuddin SIRAJUDDIN, San Jose, CA (US); Madhava Rao YALAMANCHILI, Morgan Hill, CA (US); Sonal A. SRIVASTAVA, Fremont, CA (US)

(73) Assignee: Applied Materials, Inc., Santa Clara, CA (US)

(21) Appl. No.: 14/148,385

(22) Filed: Jan. 6, 2014

Related U.S. Application Data
(60) Provisional application No. 61/751,493, filed on Jan. 11, 2013.

(51) Int. Cl. H01L 21/768

(52) U.S. Cl. CPC H01L 21/76802; H01L 21/76879
USPC 438/637

(57) ABSTRACT

The present disclosure provides methods for via reveal etching process to form through-silicon vias (TSVs) in a substrate. In one embodiment, a method for performing a via reveal process to form through-silicon vias in a substrate includes providing a substrate having partial through-silicon vias formed from a first surface of the substrate into a processing chamber, wherein the partial through-silicon vias formed in the substrate are blind vias, supplying an etching gas mixture including at least a fluorine containing gas and a chlorine containing gas into the processing chamber, and preferentially removing a portion of the substrate from a second surface of the substrate to expose the through-silicon vias until a desired length of the through-silicon vias is exposed from the second surface of the substrate.

### CROSS-REFERENCE TO RELATED APPLICATIONS

This application claims benefit of U.S. Provisional Patent Application Ser. No. 61/751,493 (APPM/016903L), filed Jan. 11, 2013, which is herein incorporated by reference.

### BACKGROUND

1. Field

Embodiments of the invention generally relate to a method for performing a via reveal process to form through-silicon vias (TSVs) in a substrate with uniform etching rate across the substrate surface.

2. Description of the Related Art

Deep recessed structure etching is one of the principal technologies currently being used to fabricate semiconductor and microstructure devices. Strict control of the etch profile is required for complex devices to perform satisfactorily. Obtaining a controlled sidewall profile and uniform through silicon via length (e.g., depth) across the substrate has proved a difficult task in many instances.

Through-silicon vias (TSVs) with uniform via length (e.g., depth) across the substrate are particularly useful in various electronic packaging applications. The TSVs enable the attachment of various components to each other, frequently in manners which enable electrical connection from device to device. Different designs of the devices may require different via depth to facilitate the bonding/packaging process. Non-uniform depth of through-silicon vias (TSVs) across the substrate may cause difficulty for the following wiring and/or packaging process, thereby resulting in device failure or poor electrical performance.

Furthermore, during a via reveal process, an etching process is often performed to expose the through-silicon vias (TSVs) from a backside of the substrate. The etching process control for the via reveal process to expose the through-silicon vias (TSVs) is often challenging. For example, when the via reveal process is performed to etch and remove excess silicon to expose the through-silicon vias (TSVs) from the substrate backside, inaccurate etching process control may adversely damage both the silicon material in the substrate as well as the conductive material layers formed within the through-silicon vias (TSVs). Improper etching process parameter control may result in defects formed both is the substrate and the through-silicon vias (TSVs) during the via reveal process. For example, improper control of RF power used during the via reveal etching process may result in insufficient depth to expose the vias through the substrate. Furthermore, improper chemistry or process parameter control may result in non-uniform via reveal height of through-silicon vias (TSVs) across the substrate.

Therefore, there requires an improved method for an etching process for revealing vias from a backside of a substrate to form TSVs in the substrate with desired profile and uniform via depth control.

### SUMMARY

The present disclosure provides methods for via reveal etching process to form through-silicon vias (TSVs) in a substrate. In one embodiment, a method for performing a via reveal process to form through-silicon vias in a substrate includes providing a substrate having partial through-silicon vias formed from a first surface of the substrate into a processing chamber, wherein the partial through-silicon vias formed in the substrate are blind vias, supplying an etching gas mixture including at least a fluorine containing gas and a chlorine containing gas into the processing chamber, and preferentially removing a portion of the substrate from a second surface of the substrate to expose the through-silicon vias until a desired length of the through-silicon vias is exposed from the second surface of the substrate.

In another embodiment, a method for performing a via reveal process to form through-silicon vias in a substrate includes providing a substrate having partial through-silicon vias formed from a first surface of the substrate into a processing chamber, wherein the partial through-silicon vias formed in the substrate are blind vias, supplying an etching gas mixture including at least a fluorine containing gas and a chlorine containing gas into the processing chamber, wherein the fluorine containing gas and the chlorine containing gas is supplied at a flow rate ratio by volume between about 5:1 and about 1:1, and preferentially removing a portion of the substrate from a second surface of the substrate to expose the through-silicon vias until a desired length of the through-silicon vias is exposed from the second surface of the substrate.

In yet another embodiment, a method for performing a via reveal process to form through-silicon vias in a substrate includes providing a substrate having partial through-silicon vias formed from a first surface of the substrate into a processing chamber, wherein the partial through-silicon vias formed in the substrate are blind vias, supplying an etching gas mixture including at least a fluorine containing gas and a chlorine containing gas into the processing chamber, wherein the fluorine containing gas and the chlorine containing gas is supplied at a flow rate ratio by volume between about 5:1 and about 1:1, and selectively etching a portion of the substrate from a second surface of the substrate, rather than to a conductive material layer filled in the through-silicon vias to expose the through-silicon vias until a desired length of the through-silicon vias is exposed from the second surface of the substrate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a schematic isometric view of an apparatus that may be used in conjunction with embodiments of the present invention to perform a via reveal etching process to form through-silicon via (TSV) in a substrate;

FIGS. 2A-2F illustrate schematic cross-sectional views of a method for forming TSVs formed in a substrate in accordance with one embodiment of the invention;

FIGS. 3A-3E illustrate schematic cross-sectional views of a method for forming TSVs formed in a substrate in accordance with another embodiment of the invention;

FIG. 4 illustrates a flow diagram of a method for performing a via reveal process to form TSVs in a substrate in accordance with one embodiment of the present invention; and

FIGS. 5A-5D illustrate schematic cross-sectional views of TSVs formed in a substrate during different stages of the method of FIG. 4.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure provides methods for performing a via reveal process to reveal vias from a backside of a substrate so as to form through-silicon vias (TSVs) in the substrate. The method employs a highly selective etching process to etch from a backside of a substrate to expose the through-silicon vias (TSVs) formed therein. The highly selective etching process may efficiently remove silicon materials from the substrate while selective to the conductive material layers and/or insulating materials formed in the through-silicon vias (TSVs). The highly selective etching process can selectively etch mostly of the silicon materials in the substrate without damage the profile of the through-silicon vias (TSVs) as well as the conductive materials and/or insulating materials formed in the through-silicon vias (TSVs). In one embodiment, a good profile and exposed through silicon via length may be controlled by maintaining good balance of the precursors supplied in an etching mixture during the etching process so as to provide a highly selective etching process and uniform etching process.

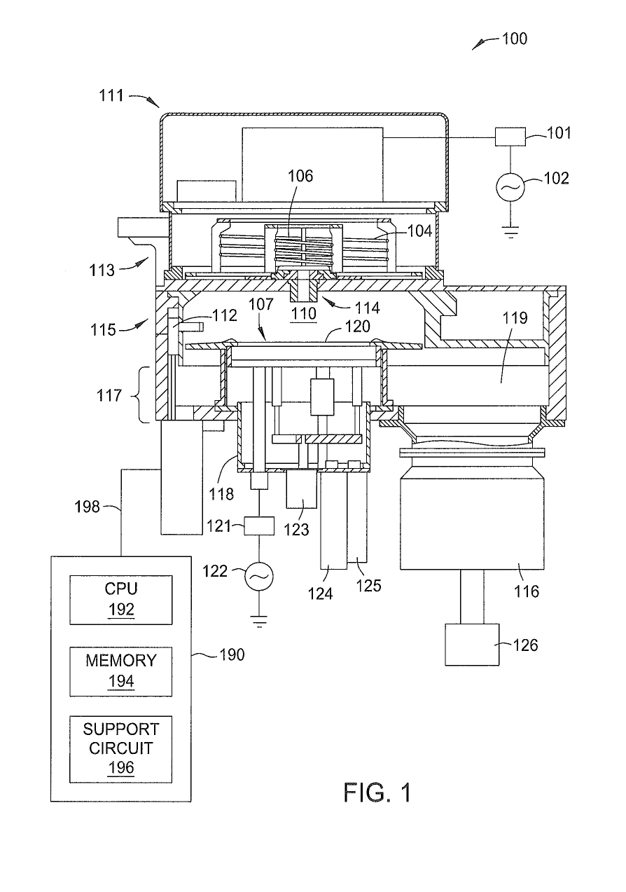

FIG. 1 depicts a schematic isometric view of a processing chamber 100 that may be used in conjunction with embodiments of the present invention to perform a via reveal etching process to form TSVs in a substrate. The via reveal etching process may be practiced in a DPS II TSV processing chamber available from Applied Materials, Inc., Santa Clara, Calif. It is contemplated that the via reveal etching process may be practiced in suitable processing chambers available from other manufactures. The DPS II TSV processing chamber may be used as part of an Integrated Processing System, also available from Applied Materials, where transfer between a combination of different processing chambers (which make up an Integrated Processing System) enables a variety of processing procedures without exposing the substrate to the ambient environment. An advantageous Integrated Processing System is the CENTURA® Mainframe System, which is also available from Applied Materials, Inc.

FIG. 1 depicts a cross sectional view of an exemplary processing chamber 100 in which the etching process further described below may be practiced. The processing chamber 100 is a fully automated semiconductor etch processing chamber of the kind which is typically employed as part of a multi-chamber, modular system (not shown) which may accommodates a variety of substrate sizes. The processing chamber 100 including a chamber body 115 having a processing volume 110 may be configured to accommodate a substrate 120 having a diameter size up to 12 inch (300 mm), 18 inch (450 mm), or other diameter.

The processing chamber 100 includes a plasma source power 102 and a matching network 101 which are in communication with a power generating apparatus present within a first enclosure 111 disposed on the chamber body 115. The plasma source power 102 and matching network 101 operate at a frequency which is typically in the range of about 12 MHz to about 13.5 MHz (while this particular processing chamber operates at this frequency, other processing chambers which may be used operate at source power frequencies ranging up to 60 MHz), at a power in the range from 0.1 kW to about 5 kW. Inductive coils 104, 106 are located within a second enclosure 113 disposed between the chamber body 115 and the first enclosure 111. The inductive coils 104, 106 may generate an RF inductively coupled plasma in the processing volume to perform a plasma process on the substrate 120 disposed on a substrate support assembly 107 disposed in the chamber body 115. A processing source gas may be introduced into the processing volume 110 through a gas exchange nozzle 114 to provide uniform controlled gas flow distribution.

The processing volume 110 present within the chamber body 115 is in communication with a lower processing chamber 117. The lower processing chamber 117 is in communication with a throttle valve 119 located above and in communication with a turbo pump 116, which is located above and in communication with a rough pump 126. In operation, plasma source gas is provided to processing volume 110 and processing by-products are pumped out of the processing volume 110 through the throttle valve 119, turbo pump 116 and rough pump 126. A substrate entry port 112 is formed in the chamber body 115 to facilitate entry and removal of the substrate 120 from the processing chamber 100.

The substrate support assembly 107 is disposed within the chamber body 115 to support the substrate 120 during processing. The substrate support assembly 107 may be a conventional mechanical or electrostatic chuck with at least a portion of the substrate support assembly 107 being electrically conductive and capable of serving as a process bias cathode. A cooling fluid supplying inlet 124 may be coupled to the substrate support assembly 107 configured to supplying cooling fluid to the substrate support assembly 107 to maintain the temperature thereof at a desired range. The substrate support assembly 107 is raised and lowered by means of a wafer lift 123 for processing.

The controller 190 includes a central processing unit (CPU) 192, a memory 194, and a support circuit 196 utilized to control the process sequence and regulate the gas flows and plasma process performed in the processing chamber 100. The CPU 192 may be of any form of a general purpose computer processor that may be used in an industrial setting. The software routines such as the etching process described below can be stored in the memory 194, such as random access memory, read only memory, floppy, or hard disk drive, or other form of digital storage. The support circuit 196 is conventionally coupled to the CPU 192 and may include cache, clock circuits, input/output systems, power supplies, and the like. Bi-directional communications between the controller 190 and the various components of the processing chamber 100 are handled through numerous signal cables collectively referred to as signal buses 198, some of which are illustrated in FIG. 1.

In one embodiment, the substrate 120 provided in the processing chamber 100 is biased by providing RF power from a RF bias power source 122 through a matching network 121 coupled to the substrate support assembly 107. RF power provided by the RF bias power source 122 may be within the range of 100 kHz to 13.56 MHz, such as within the range of 100 kHz to 2 MHz. The plasma source power 102 and the substrate RE bias power source 122 are independently controlled by the controller 190. In particular, the RF bias power source 122 is pulsed using a generator pulsing capability set by system controllers to provide a percentage of time that the power is on which is referred to as the “duty cycle.” The time on and time off of a pulsed bias power is uniform throughout substrate processing. In this instance, for example, if the power is on for 3 msec and off for 15 msec, the “duty cycle” would be 16.67%. The pulsing frequency in cycles per second (Hz) is equal to 1.0 divided by sum of the on and off time periods in seconds. For example, when the power is on for 3 msec and off for 15 msec, for a total of 18 msec, the pulsing frequency in cycles per second is 55.55 Hz. It would be possible to use a specialized pulsing profile where on/off timing changing during substrate processing for particular needs.

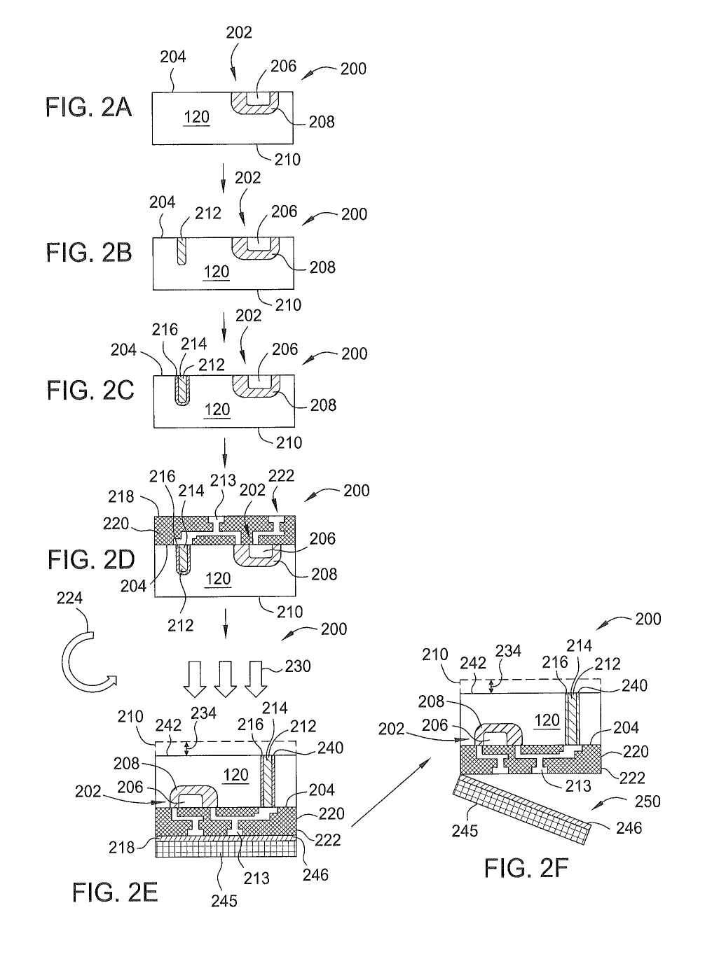

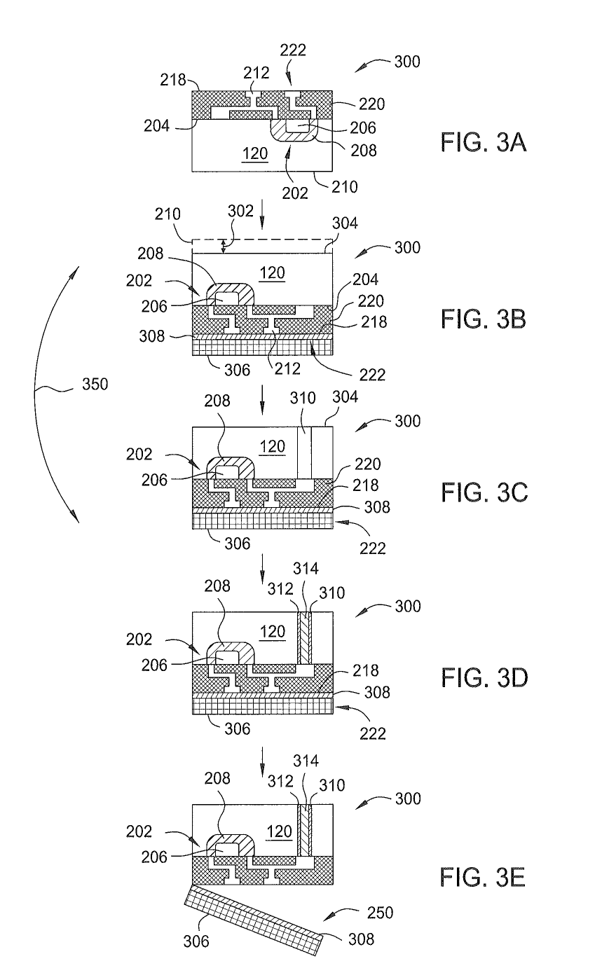

FIGS. 2A-2E depicts a flow diagram of a method for forming TSVs in a substrate in a processing chamber using a “via middle” manufacture process. The term “via middle” as described here is meant to be an order of the manufacture process as through-silicon vias (TSVs) are formed in the substrate in a middle stage, after a front end process is formed in the substrate but prior to a back end process starts, of an overall semiconductor manufacture process. A term “via last” as described later with reference to FIGS. 3A-3E is meant to be an order of the manufacture process as through-silicon vias (TSVs) are formed in the substrate in a substantially last stage of an overall semiconductor manufacture process.

The method beginning by providing a substrate 120 having a first surface 204 and a second surface 210. The first surface 204 may have a front end structure 202 formed therein. The front end structure 202 may include a device region 206 formed in a p-n well region 208 formed in and on the substrate 120. The substrate 120 may be a material such as crystalline silicon (e.g., Si<100>or Si<111>), silicon oxide, strained silicon, silicon germanium, doped or undoped polysilicon, doped or undoped silicon wafers and patterned or non-patterned wafers silicon on insulator (SOI), carbon doped silicon oxides, silicon nitride, doped silicon, germanium, gallium arsenide, glass, sapphire, metal layers disposed on silicon and the like. The substrate may have various dimensions, such as 200 mm, 300 mm or 450 mm diameter wafers, as well as, rectangular or square panels.

Subsequently, a blind through-silicon via (TSV) 212 is formed from the first surface 204 of the substrate 120, as shown in FIG. 2B. A dielectric insulating layer 216 and a conductive material layer 214 are then sequentially formed and fill in the blind through-silicon via (TSV) 212, as shown in FIG. 2G. After the through-silicon via (TSV) 212 is filled, a back end process is then performed on the first surface 204 of the substrate 120 to form a back end structure 222 on the substrate 120, as shown in FIG. 2D. The back end structure 222 may include a dielectric stack 220 having a conductive interconnection structure 213 formed therein. The back end structure 222 defines a top surface 218 on the substrate 120. The conductive interconnection structure 213 may connect to the blind through-silicon via (TSV) 212 and the front end structure 202.

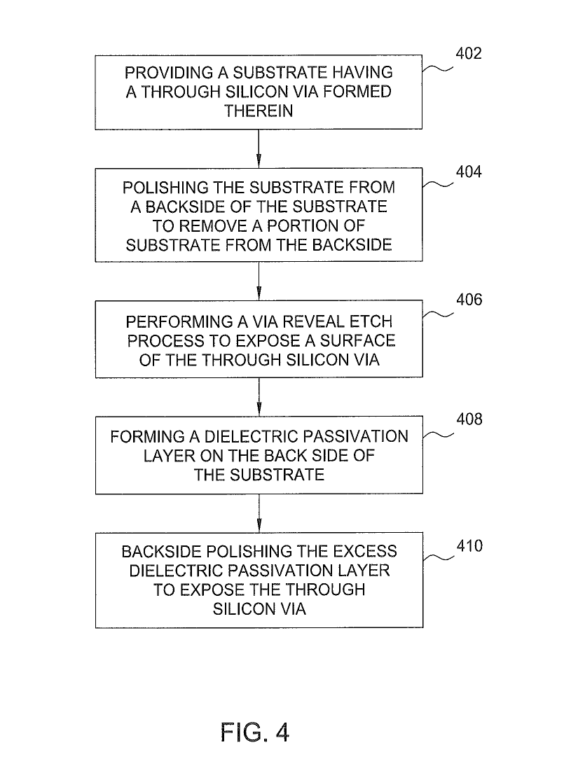

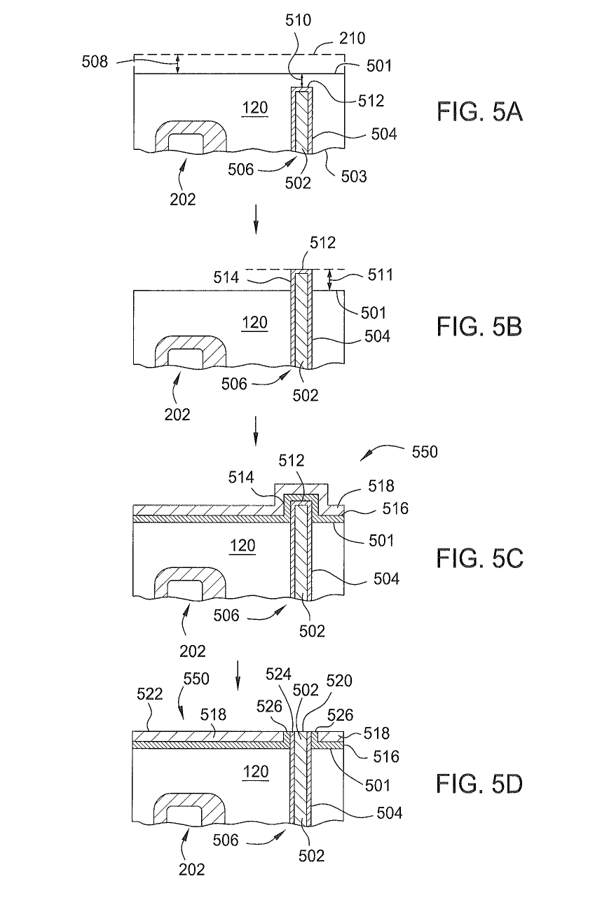

Subsequently, the substrate 120 is flipped over, as shown in the arrow 224 to perform a backside polishing process to polish the substrate 120 from the second surface 210, as shown in FIG. 2E, of the substrate 120. The backside polishing process removes a portion of the substrate 120, as shown by the arrow 230. A handling carrier 245 may be attached to the top surface 218 of the back end structure 222 through an adhesive layer 246. The handling carrier 245 is used to assist holding the substrate 120 in a secure position during the backside polishing process. The backside polishing process is continuously performed until a desired thickness 234 of the substrate 120 is removed and the through-silicon via (TSV) 212 is about to, but not yet, expose and reveal. Subsequently, a via reveal process is performed to expose the through-silicon via (TSV) 212. Details regarding how the through-silicon via (TSV) 212 is revealed and exposed are described below with referenced to FIGS. 4 and 5A-5D. After the through-silicon via 212 is exposed and revealed, a debonding process is then performed to remove the handling carrier 245 from the top surface 218 of the substrate 120 at the interface where the adhesive layer 246 is disposed, as shown in FIG. 2F.

FIGS. 3A-3E depicts a flow diagram of a method for forming TSVs in a substrate in a processing chamber using a “via last” manufacture process. The term “via last” as described here is meant to be an order of the manufacture process as through-silicon vias (TSVs) are formed in the substrate in a last stage, after a substantially overall semiconductor manufacture process is completed on the substrate.

The method is started by providing the substrate 120 having the first surface 204 and the second surface 210. Unlike the embodiment described above that the through-silicon via (TSV) 212 is formed between the front end process and the back end process, the through-silicon via (TSV) 212 is formed after both the front end process and the back end process have been completed in the substrate 120. The substrate 120 may have the front end structure 202 and the back end structure 222 formed on the first surface 204 of the substrate 120, as shown in FIG. 3A.

Subsequently, a backside polishing process is performed to polish the substrate 120 from the second surface 210, as shown in FIG. 3B, of the substrate 120. The backside polishing process removes a portion of the substrate 120 until a desired thickness 302 is removed. Similarly to the description above, a handling carrier 306, similar to the handling carrier 245, may be attached to the top surface 218 of the back end structure 222 through an adhesive layer 308. The backside polishing process is continuously performed until the desired thickness 302 of the substrate 120 is removed so as to facilitate ease of manufacturing through-silicon vias (TSV) formed therein. As the overly thick of the substrate 120 may increase difficulty in etching the vias through the body of the substrate 120, shortening the thickness of the substrate 120 may efficiently reduce etching process complexity while maintaining desired profile of the through-silicon vias (TSV) formed in the substrate 120. Subsequently, a through-silicon vias (TSV) 310 is formed in the substrate 120, as shown in FIG. 3C. Alternatively, the order of the backside polishing process and the through-silicon vias process may be reversed, as shown by the arrow 350, as needed. After the through-silicon vias (TSV) 310 is formed, a dielectric insulating layer 312 and a conductive material layer 314, similar to the dielectric insulating layer 216 and a conductive material layer 214 depicted in FIGS. 2C-2F, are then sequentially formed and filled in the through-silicon via (TSV) 310, as shown in FIG. 3D. After the through-silicon via (TSV) 212 is filled, a via reveal process is performed to remove excess materials or residuals to expose the through-silicon via (TSV) 310. Details regarding how the through-silicon via (TSV) 310 is revealed and exposed are described below with referenced to FIGS. 4 and 5A-5D. After the through-silicon via 310 is exposed and revealed, a debonding process is then performed to remove the handling carrier 306 from the top surface 218 of the substrate 120 through the adhesive layer 308, as shown in FIG. 3E.

FIG. 4 depicts a flow diagram of a method 400 for performing a via reveal process to form TSVs in a substrate in a processing chamber, such as the processing chamber 100 depicted in FIG. 1 or other suitable processing chambers. The method 400 is described with reference to FIGS. 5A-5D. The method 400 starts at block 402 by providing a substrate, such as the substrate 120 depicted in FIGS. 1-3E, into the processing chamber 100, as shown in FIG. 5A. The substrate 120 may be a material such as crystalline silicon (e.g., Si<100>or Si<111>), silicon oxide, strained silicon, silicon germanium, doped or undoped polysilicon, doped or undoped silicon wafers and patterned or non-patterned wafers silicon on insulator (SOI), carbon doped silicon oxides, silicon nitride, doped silicon, germanium, gallium arsenide, glass, sapphire, metal layers disposed on silicon and the like. The substrate may have various dimensions, such as 200 mm, 300 mm and 450 mm diameter wafers, as well as, rectangular or square panels.

Similar to the description above with reference to FIGS. 2A-2F and 3A-3E, the process 400 may have the front end structure 202 or optionally a back end structure (not shown) formed on a first side 503 of the substrate 120. It is noted that the process 400 may be performed on any kind of the substrates, including the “via middle” process, “via last” process or conventional “via first” process as needed. A through-silicon via (TSV) 506 is filled with a conductive material layer 502 and an insulating layer 504. The through-silicon via (TSV) 506 formed at this stage are sill blind vias in the substrate 120. The through-silicon via (TSV) 506 is etched and formed from the first side 503 of the substrate 120 until certain depth is reached. The substrate 120, as described above, is then flipped over to be up side down for further processing. In one embodiment, the conductive material layer 502 may be a conductive metallic material, such as copper, aluminum, tungsten, silver, gold, nickel, alloys thereof, combinations thereof, and the like. The insulating layer 504 may be a dielectric material, such as silicon oxide, silicon nitride, silicon oxynitride, or the like. In one particular embodiment, the conductive material layer 502 is a copper layer and the insulating layer 504 is a silicon oxide layer.

At block 404, a backside polishing process is performed to remove a certain thickness 508 from the second side 210 of the substrate 120, forming an exposed substrate surface 501 adjacent to a bottom 512 of the through-silicon via (TSV) 506. The polishing process may be any suitable polishing or grinding process, such as a chemical mechanical process (CMP), which may polish certain thickness 508 of the substrate 120 away as needed.

The polishing process is designed to leave a thickness 510 of the substrate 120 below the bottom 512 of the through-silicon via (TSV) 506. The thickness 510 of the remaining the substrate 120 may be later etched away at a relatively slower rate by a via reveal process, as compared to the backside polishing process, so as to maintain a desired profile of the through-silicon via (TSV) 506 and without potential damage by an overly aggressive polishing process. In one embodiment, the thickness 510 may be controlled at between about 1 μm and about 10 μm.

At block 406, subsequently, a via reveal process is performed to continue etching the substrate 120 from its exposed substrate surface 501 to reveal the bottom 512 and certain portion, e.g., sidewalls 514, of the through-silicon via (TSV) 506, as shown in FIG. 5B. The via reveal process has a high selectivity that may mainly etch the silicon materials in the substrate 120 without undesirably attacking the insulating layer 504 and the conductive material layer 502 filled in the through-silicon via (TSV) 506. By utilizing this highly selective via reveal process to reveal the through-silicon via (TSV) 506, the profile and the depth of the through-silicon via (TSV) 506 may be maintained and pertained. In one embodiment, the selectivity of via reveal process for the silicon materials to the conductive material layer and/or the insulating layer filled in the through-silicon vias during etching is controlled at greater than 100.

In one embodiment, the via reveal etching process may be performed by supplying an etching gas mixture into the processing chamber 100 to perform the via reveal process. The etching gas mixture includes at least fluorine containing gas and a chlorine containing gas. Suitable examples of the fluorine containing gas include CHF₃, NF₃, SF₆ and the like. Suitable examples of the chlorine containing gas include Cl₂, HCl, SiCl₄, BCl₃ or the like. It is believed that the chlorine containing gas supplied in the gas mixture may efficiently improve the etching uniformity across the substrate 120. In an electronegative plasma environment, such as F⁻ or Cl⁻ ions containing environment, the ion density is higher at the edge of the substrate, especially under a high pressure regime, such as greater than 40 mTorr. In absence of chlorine ions, the silicon etching rate at the substrate edge is higher than in a plasma containing fluorine ions. Therefore, by adding chlorine gas to the gas mixture, the chlorine ions form inhibiting etching byproducts, which may lower the etching rate at the edge of the substrate, thereby efficiently improving the substrate etching uniformity and exposing the bottom 512 and sidewalls 514 of the through-silicon via (TSV) 506 at a substantially uniform rate. Additionally, an inert gas, such as Ar, He, Ne, or other suitable gases, may also be supplied in the etching gas mixture as needed. In one particular embodiment, the fluorine containing gas supplied in the etching gas mixture is SF₆ and the chlorine containing gas is Cl₂. In the embodiment wherein the inert gas is utilized, an Ar gas may also be supplied in the etching gas mixture.

In one embodiment, the fluorine containing gas and the chlorine containing gas may be supplied in the etching gas mixture at a predetermined ratio. The predetermined ratio of the fluorine containing gas and the chlorine containing gas may assist providing a good balance etchants distributed across the substrate surface during etching, thereby resulting in an uniform etching rate across the substrate surface. It is believed that excess chlorine containing gas supplied in the etching gas mixture may adversely inhibit the distribution of the etchant uniformly across the substrate surface, thereby undesirably reducing the edge etching rate and limiting the capability for the etching profile control. Therefore, a good balance of the fluorine containing gas and the chlorine containing gas supplied in the etching gas mixture is an influential factor to achieve the uniform etching rate control across the substrate surface. In one embodiment, the fluorine containing gas to the chlorine containing gas may be between about 5:1 and about 1:1, such as between about 3:1 and about 1:1, for example about 1.5:1.

During etching, several process parameters may also be regulated during the etching process. In one embodiment, the chamber pressure in the presence of the etching gas mixture inside the etch chamber is regulated above 40 mTorr, such as between about 50 mTorr to about 500 mTorr, for example, between about 100 mTorr and about 200 mTorr. A substrate bias power may be applied to the substrate support assembly at a power less than 250 watts, such as between about 10 watts and about 100 watts. RF source power may be applied to maintain a plasma between about 1000 watts to about 5000 watts to maintain the plasma inside the etch chamber. A substrate temperature is maintained within a temperature range of between about −50 degrees Celsius and about 100 degrees Celsius, such as between −20 degrees Celsius to about 40 degrees Celsius.

The via reveal process may be terminated when a desired length 511 of the through-silicon via (TSV) 506 is exposed and protruded beyond the exposed substrate surface 501. In one embodiment, the length 511 of the through-silicon via (TSV) 506 is controlled at between about 2 μm and about 8 μm after the via reveal process is terminated.

At block 408, a dielectric passivation layer 550 is deposited on the substrate backside (i.e., the exposed substrate surface 501) to cover the exposed bottom 512 and sidewall 514 of the through-silicon via (TSV) 506, as shown in FIG. 5C. The dielectric passivation layer 550 may be in a single layer form or a composite film stack, such as multiple layers, as needed. In the embodiment depicted in FIG. 5C, the dielectric passivation layer 550 may include a silicon oxide layer 516 and a silicon nitride layer 518 disposed on the silicon oxide layer 516. The dielectric passivation layer 550 may serve as a back side passivation, encapsulating, or protection layer to seal the silicon materials in the substrate 120. In one embodiment, the dielectric passivation layer 550 may have a thickness between about 1 μm and about 5 μm. In the embodiment wherein the dielectric passivation layer 550 includes the silicon oxide layer 516 and the silicon nitride layer 518 disposed therein, the silicon oxide layer 516 may has a thickness between about 1 μm and about 3 μm and the silicon nitride layer 518 may has a thickness between about 0.25 μm and about 3 μm.

At block 410, after the dielectric passivation layer 550 is formed and the backside (e.g., the exposed substrate surface 501) of the substrate 120 is sealed, a final back side polishing process may then be performed to remove the excess dielectric layers on the through-silicon via (TSV) 506 to expose the conductive material layer 502 filled in the through-silicon via (TSV) 506, as shown in FIG. 5D. The exposed conductive material layer 502 is then ready to be wire bonded to perform and complete the package process as needed.

Thus, methods and apparatus for performing a via reveal process to form TSVs within a substrate are provided. By using an etching gas mixture with high selectivity of the silicon materials in the substrate to the insulating and conductive materials filled in the through-silicon via (TSV), a well control profile and dimensions of the TSVs may be contained to meet different device design requirements.

While the foregoing is directed to embodiments of the present disclosure, other and further embodiments of the disclosure may be devised without departing from the basic scope thereof, and the scope thereof is determined by the claims that follow.

1. A method for performing a via reveal process to form through-silicon vias in a substrate, comprising:
providing a substrate having partial through-silicon vias formed from a first surface of the substrate into a processing chamber, wherein the partial through-silicon vias formed in the substrate are blind vias;
supplying an etching gas mixture including at least a fluorine containing gas and a chlorine containing gas into the processing chamber; and
preferentially removing a portion of the substrate from a second surface of the substrate to expose the through-silicon vias until a desired length of the through-silicon vias is exposed from the second surface of the substrate.

2. The method of claim 1, wherein the blind vias formed from the first surface of the substrate has a bottom having a distance between about 1 μm nm and about 10 μm from the second surface of the substrate.

3. The method of claim 1, wherein the desired length of the through-silicon vias exposed from the second surface of the substrate is between about 2 μm and about 8 μm.

4. The method of claim 1, wherein the halogen containing gas is SF₆.

5. The method of claim 1, wherein the chlorine containing gas is Cl₂.

6. The method of claim 1, wherein the fluorine containing gas and the chlorine containing gas is supplied at a flow rate ratio by volume between about 5:1 and about 1:1.

7. The method of claim 1, wherein the etching gas mixture further includes an inert gas.

8. The method of claim 1, wherein supplying the etching gas mixture further comprises:
maintaining the process pressure between about 100 mTorr and about 200 mTorr.

9. The method of claim 1, wherein supplying the etching gas mixture further comprises:
applying a bias power to the substrate between about 10 Watts and about 250 Watts.

10. The method of claim 1, wherein supplying the etching gas mixture further comprises:
applying a source power to the substrate between about 1000 Watts and about 5000 Watts.

11. The method of claim 1, wherein the substrate is a silicon containing substrate.

12. The method of claim 1, wherein preferentially removing a portion of the substrate from the second surface of the substrate comprises:
selectively etching silicon materials in the substrate.

13. The method of claim 1, wherein the through-silicon vias formed in the substrate includes a conductive material layer disposed on an insulating layer filling in the through-silicon vias.

14. The method of claim 13, wherein the insulating layer is a silicon oxide layer and the conductive material layer is copper layer.

15. The method of claim 1, further comprising:
depositing a dielectric passivation layer on the exposed through-silicon vias from the second surface of the substrate.

16. The method of claim 15, further comprising:
performing a backside polishing process to remove excess dielectric passivation layer to expose a conductive material layer filled in the through-silicon vias.

17. A method for performing a via reveal process to form through-silicon vias in a substrate, comprising:
providing a substrate having partial through-silicon vias formed from a first surface of the substrate into a processing chamber, wherein the partial through-silicon vias formed in the substrate are blind vies;
supplying an etching gas mixture including at least a fluorine containing gas and a chlorine containing gas into the processing chamber, wherein the fluorine containing gas and the chlorine containing gas is supplied at a flow rate ratio by volume between about 5:1 and about 1:1; and
preferentially removing a portion of the substrate from a second surface of the substrate to expose the through-silicon vias until a desired length of the through-silicon vias is exposed from the second surface of the substrate.

18. The method of claim 17, wherein preferentially removing a portion of the substrate from a second surface of the substrate further comprises:
selectively etching silicon materials in the substrate rather than a conductive material layer or an insulating material filled in the through-silicon vias.

19. The method of claim 18, wherein the selectivity of the silicon materials to the conductive material layer or an insulating material filled in the through-silicon vias during etching is greater than 100.

20. A method for performing a via reveal process to form through-silicon vias in a substrate, comprising:
providing a substrate having partial through-silicon vias formed from a first surface of the substrate into a processing chamber, wherein the partial through-silicon vias formed in the substrate are blind vias;
supplying an etching gas mixture including at least a fluorine containing gas and a chlorine containing gas into the processing chamber, wherein the fluorine containing gas and the chlorine containing gas is supplied at a flow rate ratio by volume between about 5:1 and about 1:1; and
selectively etching a portion of the substrate from a second surface of the substrate, rather than to a conductive material layer filled in the through-silicon vias to expose the through-silicon vias until a desired length of the through-silicon vias is exposed from the second surface of the substrate.
